(19) United States
(12) Patent Application Publication
(10) Pub. No.: US 2015/0047785 A1
(43) Pub. Date: Feb. 19, 2015

(54) Plasma Processing Devices Having Multi-Port Valve Assemblies

(71) Applicant: Lam Research Corporation, Fremont, CA (US)

(72) Inventors: Michael C. Kellogg, Oakland, CA (US); Daniel A. Brown, Brentwood, CA (US); Leonard J. Sharpless, Fremont, CA (US); Allan K. Ronne, Santa Clara, CA (US)

(73) Assignee: Lam Research Corporation, Fremont, CA (US)

(21) Appl. No.: 13/965,796

(22) Filed: Aug. 13, 2013

(51) Int. Cl. H01J 37/32

(52) U.S. Cl. CPC H01J 37/32825
USPC 156/345.1

(57) ABSTRACT

A plasma processing device may include a plasma processing chamber, a plasma electrode assembly, a wafer stage, a plasma producing gas inlet, a plurality of vacuum ports, at least one vacuum pump, and a multi-port valve assembly. The multi-port valve assembly may comprise a movable seal plate positioned in the plasma processing chamber. The movable seal plate may comprise a transverse port sealing surface that is shaped and sized to completely overlap the plurality of vacuum ports in a closed state, to partially overlap the plurality of vacuum ports in a partially open state, and to avoid substantial overlap of the plurality of vacuum ports in an open state. The multi-port valve assembly may comprise a transverse actuator coupled to the movable seal plate and a sealing actuator coupled to the movable seal plate.

### BACKGROUND

The present specification generally relates to plasma processing devices and, more specifically, to valves for plasma processing devices.

### SUMMARY

Plasma processing devices typically comprise a plasma processing chamber that is connected to one or more vacuum pumps. The plasma processing device may comprise one or more valves that regulate the fluid communication between the chamber and the vacuum pumps. Embodiments described herein relate to plasma processing devices having multi-port valve assemblies. According to one embodiment, a plasma processing device may comprise a plasma processing chamber, a plasma electrode assembly, a wafer stage, a plasma producing gas inlet, a plurality of vacuum ports, at least one vacuum pump, and a multi-port valve assembly. The plasma electrode assembly and the wafer stage may be positioned in the plasma processing chamber and the plasma producing gas inlet may be in fluid communication with the plasma processing chamber. The vacuum pump may be in fluid communication with the plasma processing chamber via at least one of the vacuum ports. The multi-port valve assembly may comprise a movable seal plate positioned in the plasma processing chamber. The movable seal plate may comprise a transverse port sealing surface that is shaped and sized to completely overlap the plurality of vacuum ports in a closed state, to partially overlap the plurality of vacuum ports in a partially open state, and to avoid substantial overlap of the plurality of vacuum ports in an open state. The multi-port valve assembly may comprise a transverse actuator coupled to the movable seal plate, the transverse actuator defining a transverse range of actuation sufficient to transition the movable seal plate in a transverse direction between the closed state, the partially open state, and the open state, the transverse direction being oriented to be in predominant alignment with a sealing surface of the movable seal plate. The multi-port valve assembly may comprise a sealing actuator coupled to the movable seal plate, the sealing actuator defining a sealing range of actuation sufficient to transition the movable seal plate back and forth along a seal engaging and disengaging path between a sealed state and an un-sealed state, the seal engaging and disengaging path being oriented to be predominantly normal to the sealing surface of the movable seal plate.

In another embodiment, a plasma processing device may comprise a plasma processing chamber, a plasma electrode assembly, a wafer stage, a plasma producing gas inlet, a plurality of vacuum ports, at least one vacuum pump, and a multi-port valve assembly. The plasma electrode assembly and the wafer stage may be positioned in the plasma processing chamber. The plasma producing gas inlet may be in fluid communication with the plasma processing chamber. The vacuum pump may be in fluid communication with the plasma processing chamber via at least one of the vacuum ports. The multi-port valve assembly may comprise a movable seal plate positioned in the plasma processing chamber. The movable seal plate may comprise a transverse port sealing surface that is shaped and sized to completely overlap the plurality of vacuum ports in a closed state, to partially overlap the plurality of vacuum ports in a partially open state, and to avoid substantial overlap of the plurality of vacuum ports in an open state. The multi-port valve assembly may comprise a transverse actuator coupled to the movable seal plate, the transverse actuator defining a transverse range of actuation sufficient to transition the movable seal plate in a transverse direction between the closed state, the partially open state, and the open state, the transverse direction being oriented to be in predominant alignment with a sealing surface of the movable seal plate. The transverse actuator may comprise a rotary motion actuator and the movable seal plate comprises a rotary movable seal plate comprising a central axis. The multi-port valve assembly may comprise a sealing actuator coupled to the movable seal plate, the sealing actuator defining a sealing range of actuation sufficient to transition the movable seal plate back and forth along a seal engaging and disengaging path between a sealed state and an un-sealed state, the seal engaging and disengaging path being oriented to be predominantly normal to the sealing surface of the movable seal plate.

Additional features and advantages of the embodiments described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a cut-away front view of a plasma processing device comprising a multi-port valve assembly, according to one or more embodiments of present disclosure;

FIG. 2 schematically depicts a multi-port valve assembly in a closed state, according to one or more embodiments of present disclosure;

FIG. 3 schematically depicts a multi-port valve assembly in an open state, according to one or more embodiments of present disclosure;

FIG. 4 schematically depicts a multi-port valve assembly in a partially open state, according to one or more embodiments of present disclosure;

FIG. 5 schematically depicts a of a bearing assembly of a multi-port valve assembly, according to one or more embodiments of present disclosure;

FIG. 6 schematically depicts a cross-sectional view of the bearing assembly of FIG. 5, according to one or more embodiments of present disclosure;

FIG. 7 schematically depicts a cut-away view of the bearing assembly of FIG. 5, according to one or more embodiments of present disclosure;

FIG. 8 schematically depicts a cross-sectional view of a bearing assembly of a multi-port valve assembly, according to one or more embodiments of present disclosure;

FIG. 9 schematically depicts a cross-sectional view of a bearing assembly of a multi-port valve assembly, according to one or more embodiments of present disclosure;

FIG. 10 schematically depicts a multi-port valve assembly, according to one or more embodiments of present disclosure;

FIG. 11 schematically depicts a cross-sectional view of a bearing assembly of a multi-port valve assembly, according to one or more embodiments of present disclosure; and

FIG. 12 schematically depicts a cross-sectional view of a bearing assembly of a multi-port valve assembly, according to one or more embodiments of present disclosure.

### DETAILED DESCRIPTION

Reference will now be made in detail to various embodiments of plasma processing apparatuses, examples of which are illustrated in the accompanying drawings. Whenever possible, the same reference numerals will be used throughout the drawings to refer to the same or like parts. In one embodiment, the plasma processing device may comprise a multi-port valve assembly that may regulate fluid communication between a plasma processing chamber of the plasma processing device and vacuum pumps attached thereto. The multi-port valve assembly may comprise a movable seal plate which may be operable to seal multiple vacuum ports while in a closed position and allow for fluid communication in an open or partially open state. The seal plate may be moved between the closed and open positions with one or more actuators moving a single seal plate. As such, each vacuum port may not require its own valve assembly with separate actuator and seal plate. Additionally, the multi-port valve assemblies described herein may not require grease, which may contaminate the substrate within the plasma processing chamber or the vacuum pumps. Furthermore, the multi-port valve assemblies described herein may be contained within the plasma processing chamber, allowing for reduced size of the plasma processing device.

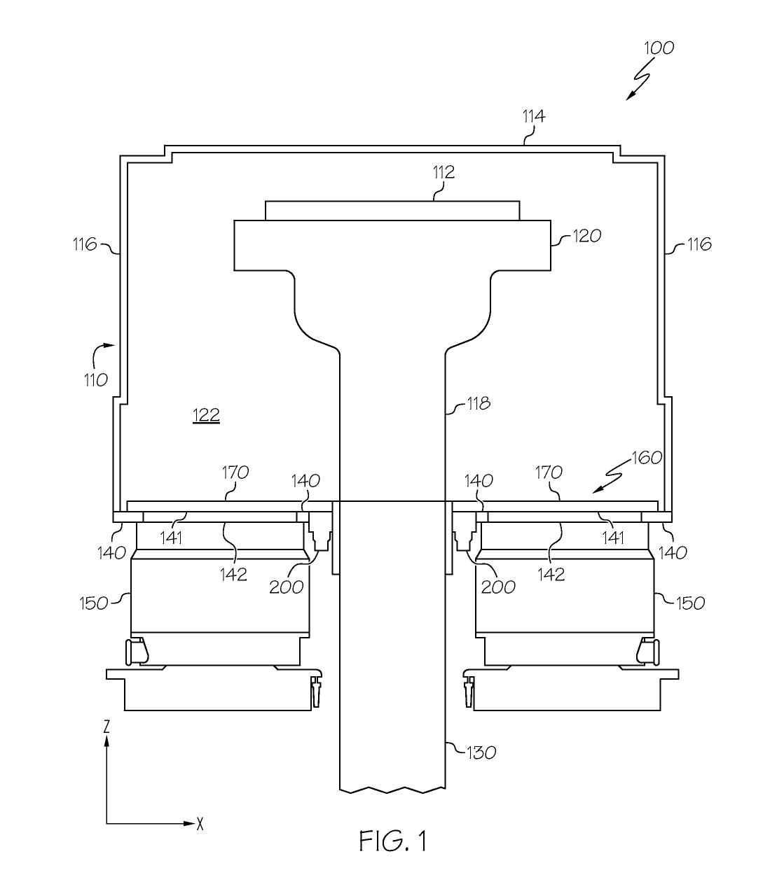

Referring to FIG. 1, a plasma processing device 100 is depicted. Generally, a plasma processing device 100 may be utilized to etch material away from a substrate 112 formed from, for example, a semiconductor, such as silicon, or glass. For example, the substrate 112 may be a silicon wafer, for example a 300 mm wafer, a 450 mm wafer, or any other sized wafer. In one embodiment, a plasma processing device 100 may comprise at least a plasma processing chamber 110, a plasma electrode assembly 118, a wafer stage 120, a plasma producing gas inlet 130, at least one vacuum pump 150, a plurality of vacuum ports 142, and a multi-port valve assembly 160. The plasma processing chamber 110 may comprise walls, such as a top wall 114, side walls 116, and a vacuum connection wall 140. A plurality of vacuum ports 142 may be disposed through vacuum connection wall 140. While the vacuum connection wall 140 is depicted on the bottom of the plasma processing chamber 110 in FIG. 1, this position is only illustrative, and the vacuum connection wall 140 may be any wall of the plasma processing chamber 110. Each of the at least one vacuum pumps 150 may be in fluid communication with the plasma processing chamber 110 via at least one of the vacuum ports 142. In one embodiment, each vacuum pump 150 is in fluid communication with the plasma processing chamber 110 via a separate vacuum port 142. For example there may be three vacuum ports 142 disposed in the vacuum connection wall 140 that each are connected to separate vacuum pumps 150, respectively.

The plasma processing chamber 110 comprises an interior region 122 within which at least the plasma electrode assembly 118 and the wafer stage 120 may be positioned. The plasma processing chamber 110 may be operable to maintain a low pressure within its interior 122, such as while the multi-port valve assembly 160 is in a closed state following operation of the vacuum pumps 150. The plasma producing gas inlet 130 may be in fluid communication with the plasma processing chamber 110 and may deliver plasma producing gas into the interior region 122 of the plasma processing chamber 110. The plasma producing gas may be ionized and transformed into a plasma state gas which may be utilized for etching the substrate 112. For example an energized source (radio frequency (RF), microwave or other source) can apply energy to the process gas to generate the plasma gas. The plasma may etch the substrate 112, such as the wafer contained in the interior region 122 of the plasma processing chamber 110. The plasma electrode assembly 118 may comprise a showerhead electrode, and may be operative to specify a pattern of etching on the substrate. For example, U.S. Pub. No. 2011/0108524 discloses one embodiment of such a plasma processing device.

The multi-port valve assembly 160 may comprise a movable seal plate 170. The movable seal plate 170 may comprise a transverse port sealing surface 141. In some embodiments, the movable seal plate 170 may be positioned in the interior region 122 of the plasma processing chamber 110. The multi-port valve assembly 160 may further comprise a bearing assembly 200. The bearing assembly 200 may be operable to constrain the movement of the movable seal plate 170. Vacuum pumps 150 are depicted that may each be in fluid communication with the plasma processing device 100 via vacuum ports 142 while the movable seal plate 170 of the multi-port valve assembly 160 is in a open or partially open state. As used herein, an “open state” refers to the state of the multi-port valve assembly 160 where there is fluid communication between the interior region 122 of the plasma processing chamber 110 and the vacuum pumps 150. As used herein, a “closed state” or “sealed state” refers to the state of the multi-port valve assembly 160 where there is not fluid communication between the interior region 122 of the plasma processing chamber 110 and the vacuum pumps 150. As used herein, the open state (sometimes referred to as “fully open state”), partially open state, and closed state can refer to either the position of the movable seal plate 170 or the position of the multi-port valve assembly 160, and the reference to either the movable seal plate 170 or the multi-port valve assembly 160 as being in a particular state may be used interchangeably. The state of fluid communication (fully open, partially open, or closed) between the vacuum pumps 150 and the interior region 122 of the plasma processing chamber 110 are determined by the position of the movable seal plate 170.

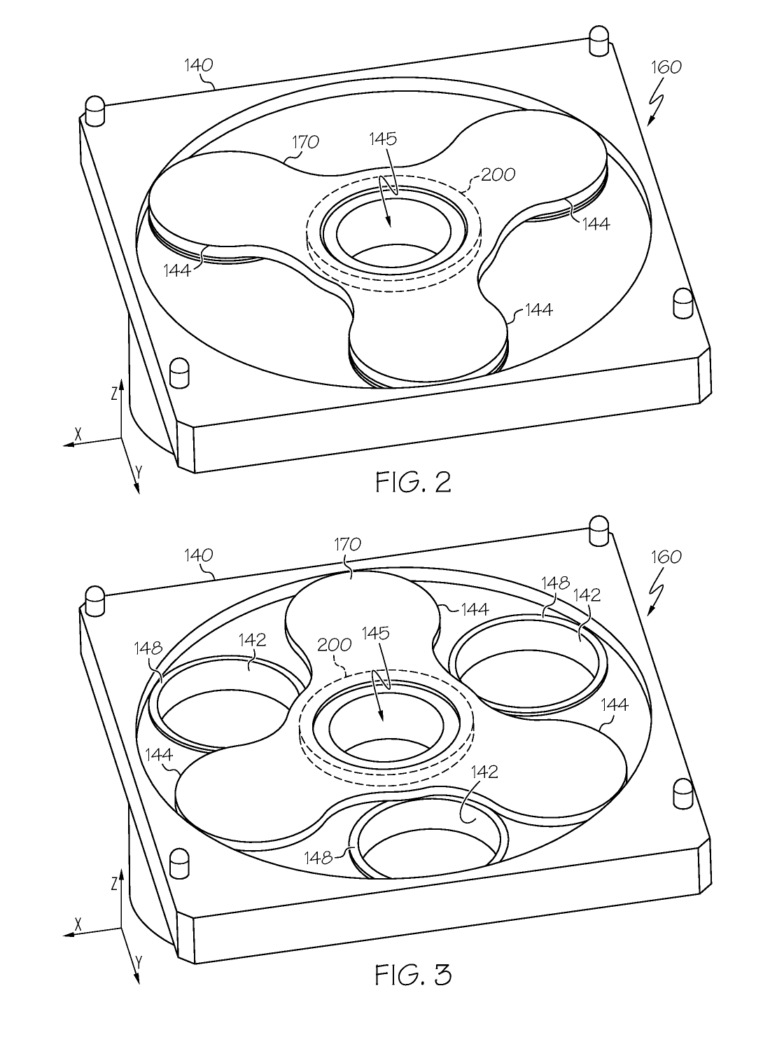

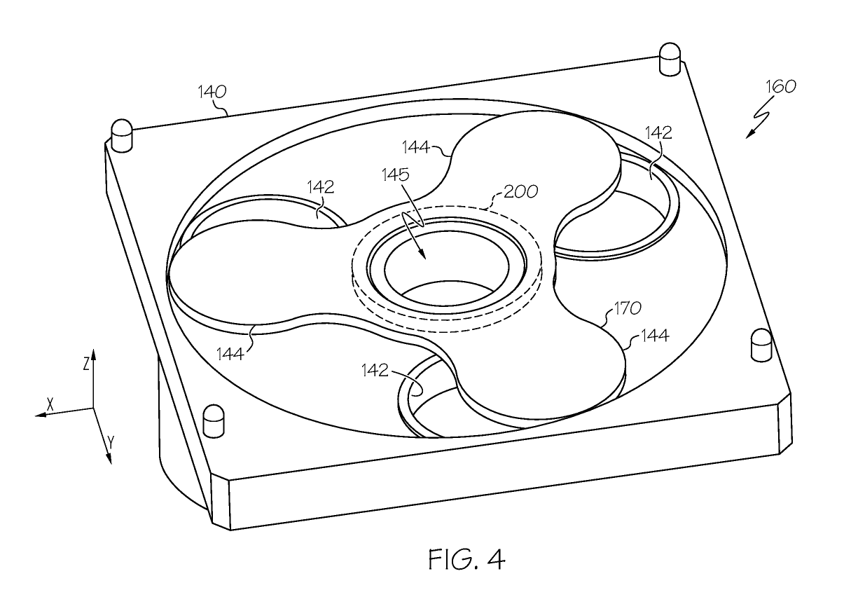

Referring now to FIGS. 1-4, the multi-port valve assembly 160 is depicted as coupled to the vacuum connection wall 140. The movable seal plate 170 may comprise a transverse port sealing surface 141 (underside of the movable seal plate 170). In one embodiment, the transverse port sealing surface 141 is substantially flat. The transverse port sealing surface 141 may be shaped and sized to completely overlap the plurality of vacuum ports 142 in a closed state (shown in FIG. 2), to partially overlap the plurality of vacuum ports 142 in a partially open state (shown in FIG. 4), and to avoid substantial overlap of the plurality of vacuum ports 142 in an open state (shown in FIG. 3). The movable seal plate 170 may comprise a unitary structure and may comprise at least two sealing lobes 144. Each sealing lobe 144 may overlap a vacuum port 142 while the movable seal plate 170 is in the closed state. The sealing lobes 144 may be sized and positioned relative to each other to overlap corresponding individual vacuum ports 142. While FIGS. 2-4 depicts a vacuum connection wall 140 comprising three vacuum ports 142 with a plate seal comprising three corresponding sealing lobes 144, the vacuum connection wall 140 may comprise any number of vacuum ports 142 with a corresponding number of sealing lobes 144. For example, FIG. 10 schematically depicts a vacuum connection wall 140 comprising two vacuum ports 142 with a movable seal plate 170 comprising two corresponding sealing lobes 144. The multi-port valve assembly 160 may comprise a bearing assembly 200. The bearing assembly 200 may be disposed under the movable seal plate 170 and may be disposed above the vacuum connection wall 140, such as between the movable seal plate 170 and the vacuum connection wall 140.

The multi-port valve assembly 160 may comprise a feed through port 145. The feed through port 145 may surround at least a portion of the plasma electrode assembly 118 when configured onto the plasma processing device 100, and may allow the multi-port valve assembly 160 to fit around the plasma processing device 100 to inhibit fluid flow between the inner portion of the plasma processing chamber 110 and the surrounding environment. In one embodiment, the feed through port 145 may be substantially circularly shaped, such as to fit around a cylinder shaped section of a plasma electrode assembly 118. However, the feed through port 145 may have any shape such as to allow for free movement of the movable seal plate 170. The movable seal plate 170 may be disposed around the feed through port 145, and may completely surround the feed through port 145 in at least two dimensions.

FIG. 2 shows a multi-port valve assembly 160 in the closed state where the movable seal plate 170 is positioned such that the transverse port sealing surface 141 completely overlaps the plurality of vacuum ports 142. The multi-port valve assembly 160 may restrict fluid communication while in the closed state and from a hermetic seal. FIG. 3 shows a multi-port valve assembly 160 in the open state where the movable seal plate 170 is positioned to avoid substantial overlap with the plurality of vacuum ports 142. The multi-port valve assembly 160 does not substantially restrict fluid communication while in the open state. FIG. 4 shows a multi-port valve assembly 160 in the partially open state where the movable seal plate 170 is positioned to partially overlap the plurality of vacuum ports 142. The multi-port valve assembly 160 partially restricts fluid communication while in the partially open state. The partially open state may be utilized to throttle the vacuum pumps 150.

As shown in FIGS. 2-4, the movable seal plate 170 may be capable of moving in the transverse direction. As used herein, the “transverse” refers to a direction being oriented to be in predominant alignment with a sealing surface of the movable seal plate 170. For example, in FIGS. 2-4, the “transverse” direction lies substantially in the plane of the x-axis and y-axis. For example the seal plate 170 may move in a rotational or rotary path, referred to herein as a rotary seal plate. In some embodiments, the movable seal plate 170 may be a rotary movable seal plate. A rotary movable seal plate 170 may be capable of rotating around a central axis. Such a rotary movable seal plate 170 is depicted in the embodiments of FIGS. 2-4.

In some embodiments, the multi-port valve assembly 160 may comprise a transverse actuator. The transverse actuator may be coupled to the movable seal plate 170 and may define a transverse range of actuation. The transverse range of actuation may be sufficient to transition the movable seal plate 170 in a transverse direction between the closed state, the partially open state, and the open state. The transverse actuator may be any mechanical component capable of transitioning the movable seal plate 170 in a transverse direction, such as between the open and closed states. In one embodiment, the transverse actuator may be coupled by direct mechanical contact with the movable seal plate 170. In another embodiment, the transverse actuator may be coupled through non-contacting means, such as by magnetism. In one embodiment, the transverse actuator comprises a rotary motion actuator which can cause the movable seal plate 170 to rotate around a central axis.

The movable seal plate 170 may be capable of moving in a seal engaging/disengaging path. As used herein, the “engaging path” or “disengaging path” refers to the path being oriented to be in predominant alignment with the sealing surface of the movable seal plate 170. For example, in FIGS. 2-4, the engaging path direction is substantially that of the z-axis. The movable seal plate 170 may be operable to move at least about 2 mm, 4 mm, 6 mm, 8 mm 10 mm, 12 mm, 20 mm, 50 mm, or more in the direction of the seal engaging/disengaging path. In one embodiment, the seal plate is operable to move between about 10 mm and about 15 mm in the direction of the seal engaging/disengaging path.

In some embodiments, the multi-port valve assembly 160 may comprise a sealing actuator. The sealing actuator may be coupled to the movable seal plate 170 and may define a sealing range of actuation. The sealing range of actuation may be sufficient to transition the movable seal plate 170 back and forth along the seal engaging and disengaging path between a sealed state and an un-sealed state. In one embodiment, the sealing actuator may be coupled by direct mechanical contact with the movable seal plate 170. In another embodiment, the sealing actuator may be coupled through non-contacting means, such as by magnetism.

In one embodiment, the movable seal plate 170 may be capable of moving in both the transverse direction and seal engaging/disengaging path direction.

Referring now to FIG. 3, in one embodiment, the multi-port valve assembly 160 may comprise at least one o-ring 148. The o-ring 148 may be positioned around one or more of the vacuum ports 142. The movable seal plate 170 may be in direct contact with each o-ring 148 while the movable seal plate 170 is in the closed state. The o-rings 148 may help to form a hermetic seal while the movable seal plate 170 is in the close state.

In one embodiment, the movable seal plate 170 transitions between the closed, partially open, and open states by movement of the seal plate 170 in both the transverse and sealing directions. In some embodiments, the movement of the seal plate 170 in the transverse and sealing directions may actuated by the transverse actuator and the sealing actuator, respectively. In other embodiments, the transverse actuator and the sealing actuator may comprise a single actuator that may actuate motion of the seal plate 170 in both the transverse and sealing directions.

In one embodiment, the closed state depicted in FIG. 2 may comprise the movable seal plate 170 in contact with the vacuum connection wall 140 and overlapping the vacuum ports 142. A hermetic seal may be formed. The movable seal plate 170 may be held towards the vacuum connection wall 140 in the z-axis direction by the sealing actuator.

To move to the partially open state, the sealing actuator may cause movement of the movable seal plate 170 in the z-axis direction away from the vacuum connection wall 140. Following movement by the movable seal plate 170 away from the vacuum connection wall 140, the transverse actuator may cause movement of the movable seal plate 170 in the transverse direction, such as rotation of the movable seal plate 170 to the partially open state depicted in FIG. 4. The movable seal plate 170 may be further rotated to achieve the open state depicted in FIG. 3. For example, the seal plate 170 may only need to rotate about 60° between the open and closed states in the embodiment of FIG. 2.

To move the movable seal plate 170 from the open state to the closed state, the transverse actuator may cause movement of the movable seal plate 170 in the transverse direction, such as rotation of the movable seal plate 170 to the partially open state depicted in FIG. 4. The movable seal plate 170 may be further rotated by the transverse actuator until it is completely overlapping the vacuum ports 142. Once the movable seal plate 170 is overlapping the vacuum ports 142, the sealing actuator may move the movable seal plate 170 towards the vacuum connection wall 140 until a hermetic seal is created which does not permit fluid communication between the plasma processing chamber 110 and the vacuum pumps 150.

In other embodiments, the movable seal plate 170 may move between open and closed states without utilizing movement in the z-axis direction. For example, the movable seal plate 170 may slide across the vacuum connection wall 140, staying always in contact with the vacuum connection wall 140. In another embodiment, the movable seal plate 170 may move between open and closed states without utilizing movement in transverse direction. For example, the movable seal plate 170 may move only in the z-axis direction to allow for fluid communication and disallow fluid communication.

Referring to FIGS. 1 and 5-7, the multi-port valve assembly 160 may further comprise a bearing assembly 200. The bearing assembly 200 may be operable to constrain the movement of the movable seal plate 170 in the transverse direction, a direction of the seal engaging and disengaging path, or both. While several embodiments of bearing assemblies 200 are disclosed herein, it should be understood that the bearing assembly 200 may be any mechanical or other device or system capable restricting the movement of the movable seal plate 170. For example, in one embodiment, the bearing assembly 200 may define a range of motion constrained by a guiding means such as a track 186.

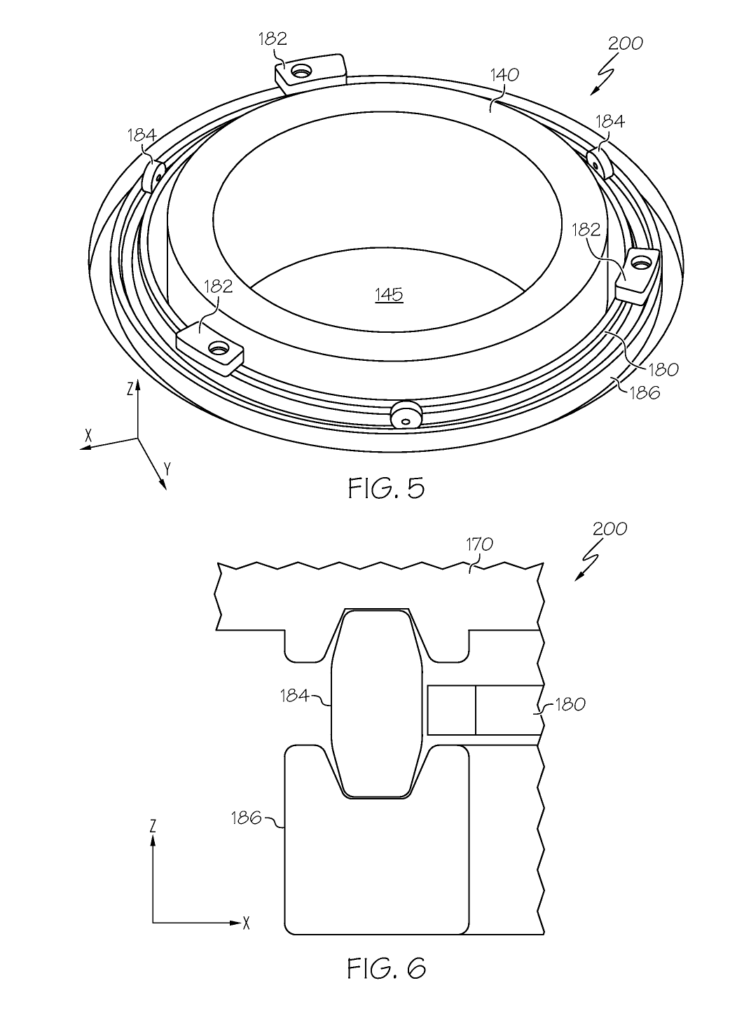

Referring now to FIGS. 5-7, in one embodiment, the bearing assembly 200 comprises a track 186 and a carriage 180 comprising wheels 184. The wheels 184 may be coupled to the carriage 180 such that the wheels 184 may turn and allow for movement of the carriage 180. FIG. 5 shows a cut-away view of an embodiment of such a bearing assembly 200 comprising wheels 184 on a track 186. The wheels 184 may rest in direct contact with the track 186. The track 186 and carriage 180 may be circular, and define a circular range of motion of the wheels 184. The bearing assembly 200 may further comprise one or more plate attaching members 182 which may be mechanically coupled to the movable seal plate 170 (not shown in FIG. 5) and translate motion of the sealing actuator to the movable seal plate 170.

Referring now to FIG. 6, a cross-sectional view through the wheel section of the bearing assembly 200 of FIG. 5 is shown. The wheel 184 may be coupled to the carriage 180 such that the wheel 184 is free to rotate and move in the direction of the track 186, which may be circular. The wheel 184 may be in contact with and between the track 186 and the movable seal plate 170. The wheels 184 may allow for free movement of the movable seal plate 170 in a rotational direction relative to the track 186.

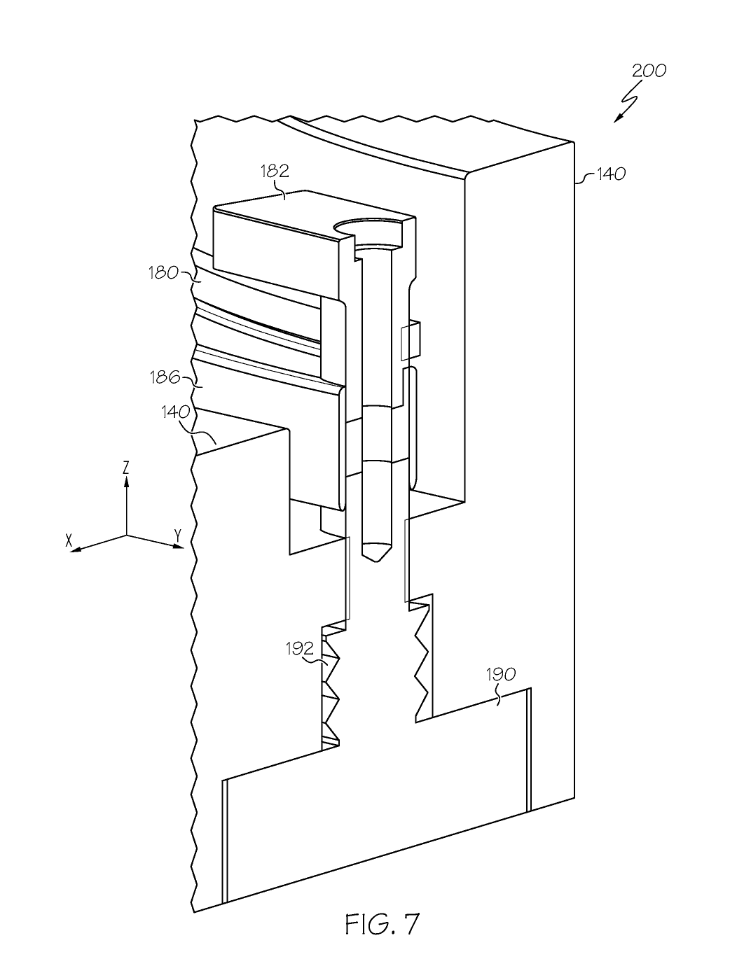

Referring now to FIG. 7, a cut-away view of the bearing assembly 200 of FIG. 5 is shown which shows a plate attaching member 182. The plate attaching members 182 may be mechanically coupled to the track 186 and the track 186 may be mechanically coupled to an actuator coupling attachment 190. In one embodiment, the actuator coupling attachment 190 may comprise the sealing actuator. For example, the actuator coupling attachment 190 may be a pneumatic actuator that is capable of causing movement in the z-axis direction of the plate attaching member 182, carriage 180, track 186, and causing movement in the z-axis direction of the movable seal plate 170. The actuator coupling attachment 190 may operate as a vacuum seal to seal the vacuum portion of the chamber from the surrounding atmosphere. In some embodiments, the actuator coupling attachment 190 may comprise bellows 192. The bellows 192 may serve to separate the vacuum portion of the chamber from the surrounding atmosphere region 122 of the plasma processing chamber 110 when the actuator coupling attachment 190 moves in the z-axis direction.

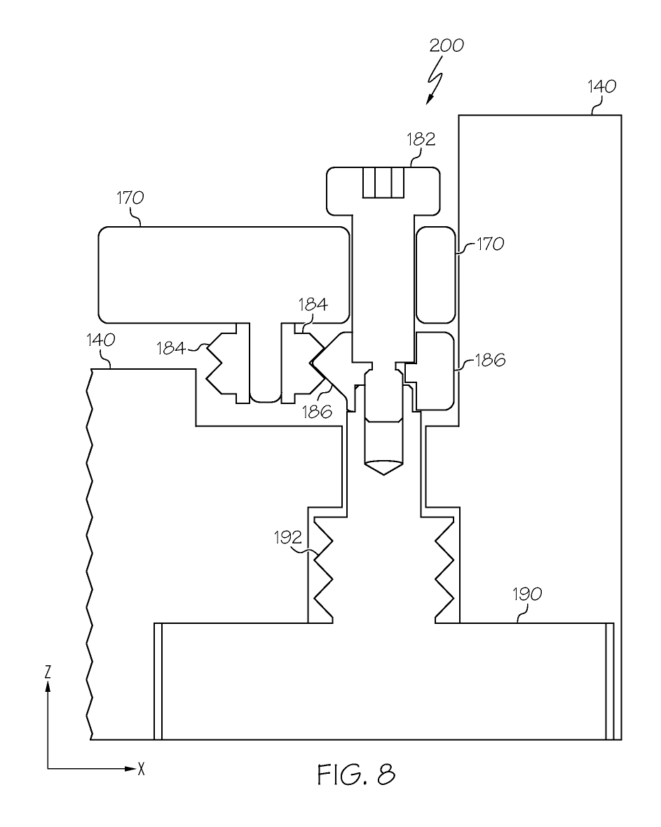

Referring now to FIG. 8, a cross sectional view of another embodiment of a bearing assembly 200 is shown. In such an embodiment, the bearing assembly 200 may comprise wheels 184 which are oriented in the transverse direction with respect to the track 186. The bearing assembly 200 may comprise a plate attaching member 182 and actuator coupling attachment 190 which are coupled to the track 186, respectively. In the embodiment of FIG. 8, the wheels 184 may be grooved to match a contoured track 186. The wheels 184 may be coupled to the movable seal plate 170 directly. FIG. 8 shows the plate attaching member 182 coupled to the movable seal plate 170, which allows for the plate attaching members 182 to translate movement to the movable seal plate 170. In such an embodiment, the track 186 and plate attaching member 182 remain stationary while the movable seal plate 170 rotates on the wheels 184. The plate attaching member 182 does not actuate movement of the seal plate 170 in the transverse direction, but does actuate movement of the seal plate 170 in the sealing direction when the actuator coupling attachment 190 is moved in the z-axis direction by the sealing actuator, such as a pneumatic actuator.

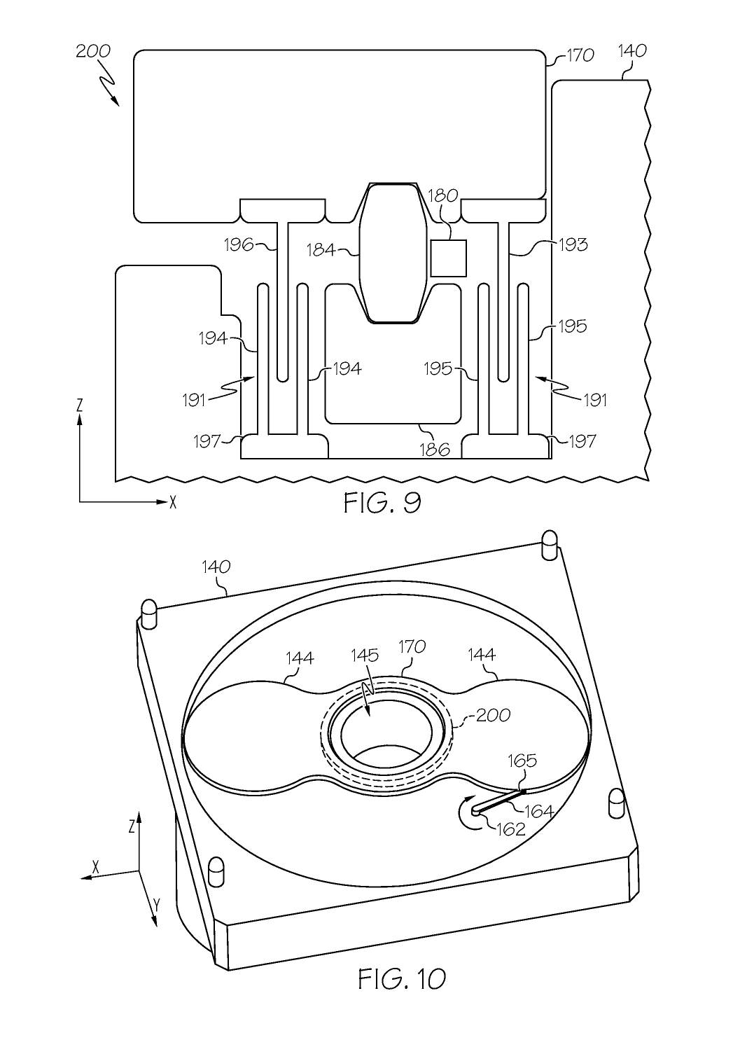

Referring now to FIG. 9, another embodiment of the multi-port valve assembly 160 is shown. In some embodiments, the multi-port valve assembly 160 may comprise a labyrinth design 191 comprising interleaved sealing extensions 193,194,195,196. In one embodiment, at least one sealing extension 193,196 may emanate from the movable seal plate 170 and at least one sealing extension 194,195 may emanate from a chamber member 197 opposite the sealing surface of the movable seal plate 170. However, any number of sealing extensions 193,194,195,196 may emanate from either a chamber member 197 or movable seal plate 170. In one embodiment, the multi-port valve assembly 160 may comprise the labyrinth design 191 on each side of the wheels 184. The labyrinth design 191 may be operable to obstruct the passage of particles from the interior region 122 of the plasma processing chamber 110 to the exterior of the plasma processing chamber 110 and the passage of particles from the exterior of the plasma processing chamber 110 to the interior region 122 of the plasma processing chamber 110.

In one embodiment of the plasma processing device 100 comprising a labyrinth design 191, the sealing actuator may actuate movement of the movable seal plate 170, carriage 180, wheels 184, track 186, sealing extension 196, and sealing extension 193 in the sealing direction. The vacuum connection wall 140, sealing extensions 194, 195, and chamber members 197 may remain stationary.

In one embodiment, at least a portion of the multi-port valve assembly 160 may be electrostatically charged. Electrostatically charged, as used herein, refers to an electrical charge running through the section of the multi-port valve assembly 160. For example, in one embodiment, at least one of the interleaved sealing extensions 193,194,195,196 may be electrostatically charged. The charge may serve to attract or detract particles. For example, the charge may be operable to obstruct the passage of particles from the interior region 122 of the plasma processing chamber 110 to the exterior of the plasma processing chamber 110 and the passage of particles from the exterior of the plasma processing chamber 110 to the interior region 122 of the plasma processing chamber 110.

Referring now to FIG. 10, in one embodiment, the transverse actuator may comprise a mechanical crank 164. The mechanical crank 164 may be operable to move the seal plate 170 in the transverse direction. The mechanical crank 164 may comprise a crank shaft 162 coupled to the movable seal plate 170 at a coupling point 165. The coupling point 165 may mechanically couple the mechanical crank 164 to the movable seal plate 170 while allowing the coupling point 165 to slide along the edge of the movable seal plate 170. The crank shaft 162 may rotate to move the movable seal plate 170 in the transverse direction. The 162 may rotate causing coupling point 165 to slide along the edge of movable seal plate 170 and translate movement to the movable seal plate 170. In one embodiment, the crank shaft 162 may extend from the exterior of the plasma processing chamber 110 to the interior region 122 of the plasma processing chamber 110. The rotation of the crank shaft 162 may be controlled by a motor or other mechanical means.

In another embodiment, the transverse actuator may comprise a magnetic system. For example, the seal plate 170 may comprise a first magnetic component which may be magnetically coupled to a second magnetic component that is positioned outside of the plasma processing chamber 110. The movement of the second magnetic component may actuate motion of the movable seal plate 170 in the transverse direction.

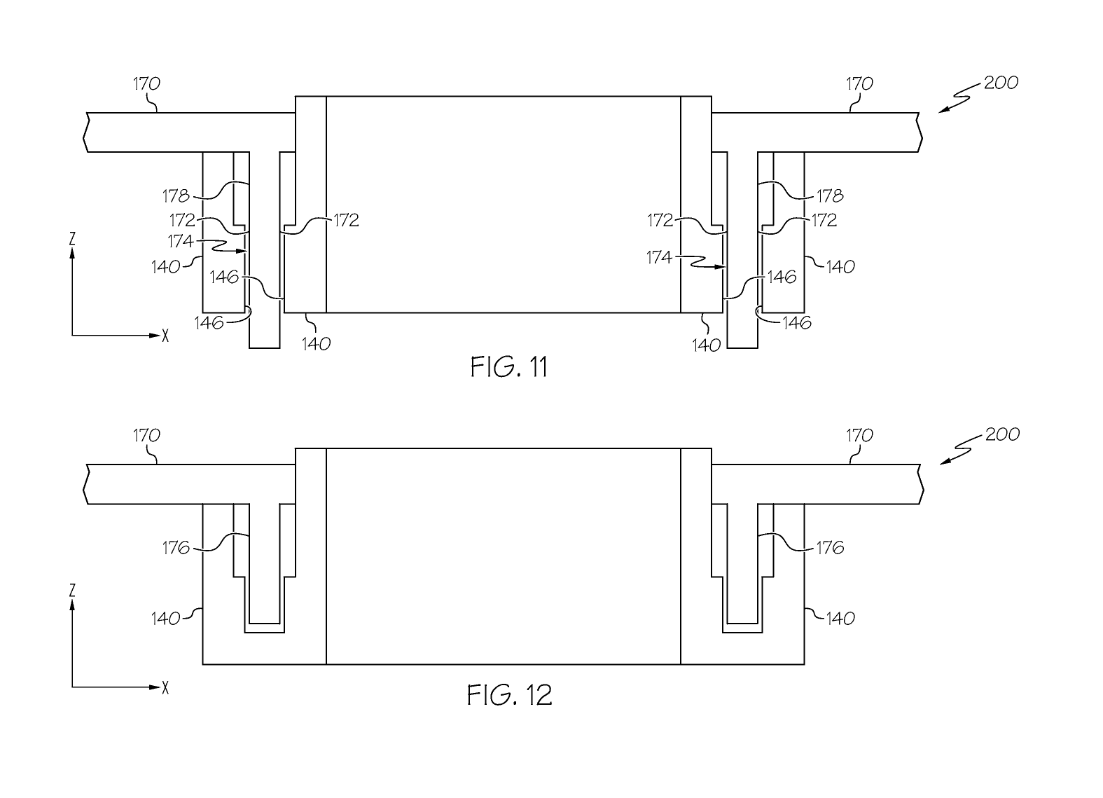

In another embodiment, the multi-port valve assembly 160 may comprise a ferro-fluidic seal 174. FIG. 11 shows a cross sectional view of an embodiment of a ferro-fluidic seal 174. The ferro-fluidic seal 174 may comprise a ferro-fluid 172. In one embodiment, the movable seal plate 170 may comprise a plate member 178, and the ferro-fluid 172 may be positioned between the plate member 178 of the movable seal plate 170 and a chamber member 146 opposite the sealing surface of the movable seal plate 170. The ferro-fluidic seal 174 may be a magnetic liquid sealing system that may be used to rotate the movable seal plate 170 while maintaining a hermetic seal by means of a physical barrier in the form of the ferro-fluid 172.

In another embodiment, the multi-port valve assembly 160 may comprise a magnetic actuator system. The magnetic actuator system may be operable to levitate the movable seal plate 170. FIG. 12 shows a cross section view of an embodiment of a levitating seal plate 170. The seal plate 170 may comprise a plate member 176 that is contoured to the shaped of the vacuum connection wall 140. The movable seal plate 170 may comprise a first magnetic component. The first magnetic component may be magnetically coupled to a second magnetic component that is positioned outside of the plasma processing chamber 110. The magnetic system may actuate the movement of the movable seal plate 170 in the transverse and sealing directions.

In such one embodiment, the transverse actuator may comprise a magnetic actuator system and the sealing actuator may comprise a magnetic actuator system. The transverse actuator and the sealing actuator may comprise the same magnetic actuator system. In the embodiment shown in FIG. 12, the magnetic actuator system is operable to levitate the movable seal plate 170 and actuate its motion from the closed to open states and vice versa.

While various embodiments of mechanical systems operable to actuate and/or constrain the motion of the movable seal plate 170 in the transverse direction, sealing direction, or both, it should be understood that these are illustrative and other mechanical embodiments may be used to transition the movable seal plate 170 between the closed, partially open, and open states.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

Various modifications and variations can be made to the embodiments described herein without departing from the scope of the claimed subject matter. Thus it is intended that the specification cover the modifications and variations of the various embodiments described herein provided such modification and variations come within the scope of the appended claims and their equivalents.

1. A plasma processing device comprising a plasma processing chamber, a plasma electrode assembly, a wafer stage, a plasma producing gas inlet, a plurality of vacuum ports, at least one vacuum pump, and a multi-port valve assembly, wherein:
the plasma electrode assembly and the wafer stage are positioned in the plasma processing chamber;
the plasma producing gas inlet is in fluid communication with the plasma processing chamber;
the vacuum pump is in fluid communication with the plasma processing chamber via at least one of the vacuum ports;
the multi-port valve assembly comprises a movable seal plate positioned in the plasma processing chamber;
the movable seal plate comprises a transverse port sealing surface that is shaped and sized to completely overlap the plurality of vacuum ports in a closed state, to partially overlap the plurality of vacuum ports in a partially open state, and to avoid substantial overlap of the plurality of vacuum ports in an open state;
the multi-port valve assembly comprises a transverse actuator coupled to the movable seal plate, the transverse actuator defining a transverse range of actuation sufficient to transition the movable seal plate in a transverse direction between the closed state, the partially open state, and the open state, the transverse direction being oriented to be in predominant alignment with a sealing surface of the movable seal plate; and
the multi-port valve assembly comprises a sealing actuator coupled to the movable seal plate, the sealing actuator defining a sealing range of actuation sufficient to transition the movable seal plate back and forth along a seal engaging and disengaging path between a sealed state and an un-sealed state, the seal engaging and disengaging path being oriented to be predominantly normal to the sealing surface of the movable seal plate.

2. The plasma processing device of claim 1, wherein the transverse actuator comprises a rotary motion actuator and the movable seal plate comprises a rotary movable seal plate comprising a central axis.

3. The plasma processing device of claim 2, wherein:
the rotary movable seal plate comprises a plurality of sealing lobes; and
the sealing lobes are sized and positioned relative to each other to overlap corresponding individual vacuum ports.

4. The plasma processing device of claim 2, wherein the movable seal plate may overlap multiple vacuum ports.

5. The plasma processing device of claim 1, wherein the multi-port valve assembly further comprises a bearing assembly operable to constrain the movement of the movable seal plate in the transverse direction, a direction of the seal engaging and disengaging path, or both.

6. The plasma processing device of claim 5, wherein the bearing assembly comprises a track and a carriage comprising wheels, the wheels positioned in contact with and between the track and the movable seal plate.

7. The plasma processing device of claim 1, wherein at least a portion of the multi-port valve assembly is electrostatically charged.

8. The plasma processing device of claim 1, wherein the multi-port valve assembly comprises a labyrinth design comprising interleaved sealing extensions, wherein at least one sealing extension emanates from the movable seal plate and at least one sealing extension emanates from a chamber member opposite the sealing surface of the movable seal plate.

9. The plasma processing device of claim 8, wherein at least one of the interleaved sealing extensions is electrostatically charged.

10. The plasma processing device of claim 1, wherein the multi-port valve assembly comprises a ferro-fluidic seal comprising a ferro-fluid positioned between the movable seal plate and a chamber member opposite the sealing surface of the movable seal plate.

11. The plasma processing device of claim 1, wherein the transverse actuator comprises a magnetic actuator system.

12. The plasma processing device of claim 1, wherein the transverse actuator comprises a mechanical crank comprising a crank shaft coupled to the movable seal plate, wherein:
the crank shaft rotates to move the movable seal plate in the transverse direction; and
the crank shaft extends from the exterior of the plasma processing chamber to the interior of the plasma processing chamber.

13. The plasma processing device of claim 1, wherein the transverse actuator and the sealing actuator comprise a magnetic actuator system.

14. The plasma processing device of claim 13, wherein and magnetic actuator system is operable to levitate the movable seal plate.

15. The plasma processing device of claim 1, wherein plasma processing device further comprises an o-ring positioned around each vacuum port, the movable seal plate in direct contact with each o-ring while the movable seal plate is in the closed state.

16. A plasma processing device comprising a plasma processing chamber, a plasma electrode assembly, a wafer stage, a plasma producing gas inlet, a plurality of vacuum ports, at least one vacuum pump, and a multi-port valve assembly, wherein:
the plasma electrode assembly and the wafer stage are positioned in the plasma processing chamber;
the plasma producing gas inlet is in fluid communication with the plasma processing chamber;
the vacuum pump is in fluid communication with the plasma processing chamber via at least one of the vacuum ports;
the multi-port valve assembly comprises a movable seal plate positioned in the plasma processing chamber;
the movable seal plate comprises a transverse port sealing surface that is shaped and sized to completely overlap the plurality of vacuum ports in a closed state, to partially overlap the plurality of vacuum ports in a partially open state, and to avoid substantial overlap of the plurality of vacuum ports in an open state;
the multi-port valve assembly comprises a transverse actuator coupled to the movable seal plate, the transverse actuator defining a transverse range of actuation sufficient to transition the movable seal plate in a transverse direction between the closed state, the partially open state, and the open state, the transverse direction being oriented to be in predominant alignment with a sealing surface of the movable seal plate;
the transverse actuator comprises a rotary motion actuator and the movable seal plate comprises a rotary movable seal plate comprising a central axis; and
the multi-port valve assembly comprises a sealing actuator coupled to the movable seal plate, the sealing actuator defining a sealing range of actuation sufficient to transition the movable seal plate back and forth along a seal engaging and disengaging path between a sealed state and an un-sealed state, the seal engaging and disengaging path being oriented to be predominantly normal to the sealing surface of the movable seal plate.

17. The plasma processing device of claim 16, wherein the multi-port valve assembly further comprises a bearing assembly operable to constrain the movement of the movable seal plate in the transverse direction, a direction of the seal engaging and disengaging path, or both.

18. The plasma processing device of claim 17, wherein the bearing assembly comprises a track and a carriage comprising wheels, the wheels positioned in contact with and between the track and the movable seal plate.

19. The plasma processing device of claim 16, wherein at least a portion of the multi-port valve assembly is electrostatically charged.

20. The plasma processing device of claim 16, wherein the multi-port valve assembly comprises a labyrinth design comprising interleaved sealing extensions, wherein at least one sealing extension emanates from the movable seal plate and at least one sealing extension emanates from a chamber member opposite the sealing surface of the movable seal plate.
